(19) United States
(12) Patent Application Publication
(10) Pub. No.: US 2013/0301365 A1
(43) Pub. Date: Nov. 14, 2013

(54) DEDICATED REFERENCE VOLTAGE GENERATION CIRCUIT FOR MEMORY

(71) Applicants: Bo TIAN, Shenzhen (CN); Kang WU, Shenzhen (CN)

(72) Inventors: Bo TIAN, Shenzhen (CN); Kang WU, Shenzhen (CN)

(21) Appl. No.: 13/680,059

(22) Filed: Nov. 18, 2012

(30) Foreign Application Priority Data
Feb. 10, 2012 (CN) 201210029439.8

(51) Int. Cl. G11C 5/14

(52) U.S. Cl. CPC G11C 5/147
USPC 365/189.09

(57) ABSTRACT

A memory includes a data pin, an address pin, and a reference voltage generation circuit. The reference voltage generation circuit includes a first reference voltage generation circuit and a second reference voltage generation circuit. The first reference voltage generation circuit is electronically connected to the data pin, and supplies a reliable first reference voltage to the data pin. The second reference voltage generation circuit is electronically connected to the address pin, and supplies a reliable second reference voltage to the address pin.

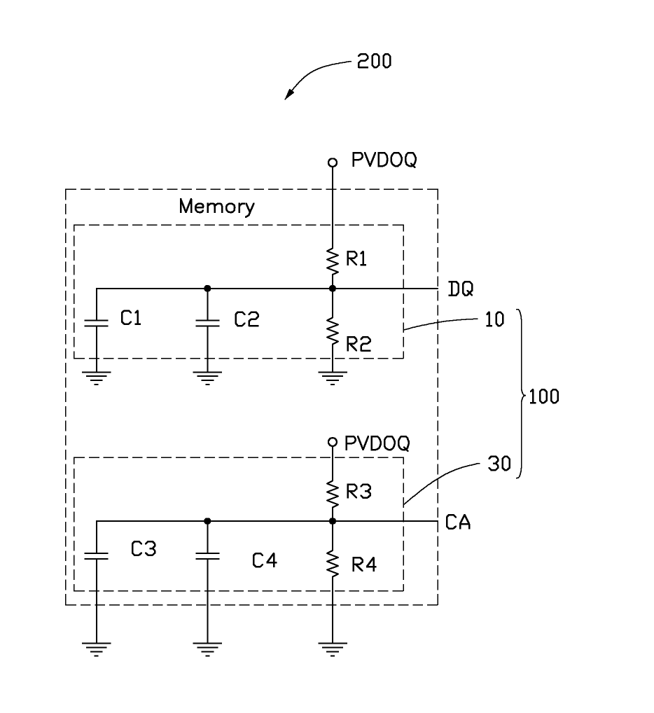

### BACKGROUND

1. Technical Field

The disclosure generally relates to reference voltage generation circuits, and particularly to a reference voltage generation circuit for a memory.

2. Description of the Related Art

Many electronic devices, such as servers, comprise a motherboard and a memory positioned on the motherboard. The motherboard further includes a microchip to generate a first reference voltage for a data pin of the memory and a second reference voltage for an address pin of the memory. However, the first reference voltage and the second reference voltage may be distorted in a transmission process from the motherboard to the memory. Additionally, the electronic devices may incur increased costs because of use of the microchip.

Therefore, there is room for improvement within the art.

### BRIEF DESCRIPTION OF THE DRAWINGS

Many aspects of the present disclosure can be better understood with reference to the drawing. The components in the drawings are not necessarily drawn to scale, the emphasis instead being placed upon clearly illustrating the principles of the present embodiments.

The FIGURE is a circuit view of a reference voltage generation circuit for a memory, according to an exemplary embodiment.

### DETAILED DESCRIPTION

The FIGURE shows a reference voltage generation circuit 100, which can be used in an electronic device such as personal computer, server. The electronic device includes a motherboard (not shown) and a memory 200. The reference voltage generation circuit 100 is integrated on the memory 200. In one exemplary embodiment, the motherboard supplies a power supply PVDDQ of about 1.5V.

The memory 200 further includes a data pin DQ and an address pin CA. The data pin DQ is configured to receive/transmit data signals, and the address pin CA is configured to receive/transmit address signals.

The reference voltage generation circuit 100 includes a first reference voltage generation circuit 10 and a second reference voltage generation circuit 30.

The first reference voltage generation circuit 10 supplies a first reference voltage to the data pin DQ. In one exemplary embodiment, the first reference voltage generation circuit 10 includes a first resistor R1, a second resistor R2, a first capacitor C1, and a second capacitor C2. The first resistor R1 and the second resistor R2 are electronically connected in series between the power supply PVDDQ and ground. In one exemplary embodiment, the resistance value of the first resistor R1 and the second resistor R2 is about 100±0.5% ohms The data pin DQ is electronically connected between the first resistor R1 and the second resistor R2, thus the first reference voltage generation circuit 10 supplies the first reference voltage of about 0.75V to the data pin DQ. The first capacitor C1 is electronically connected to the second capacitor C2 in parallel. A first end of the first capacitor C1 is electronically connected between the first resistor R1 and the second resistor R2, and a second end of the first capacitor C1 is connected to ground. A first end of the second capacitor C2 is electronically connected between the first resistor R1 and the second resistor R2, and a second end of the second capacitor C2 is connected to ground. Thus, any ripple of the first reference voltage is filtered by the first capacitor C1 and the second capacitor C2.

The first reference voltage generation circuit 10 is integrated on the memory 200, and is adjacent to the data pin DQ. Thus, signal transmission length from the motherboard to the memory 200 is reduced, and it is less likely that the first reference voltage will be interfered with and distorted in the transmission process from the first reference voltage generation circuit 10 to the data pin DQ.

The second reference voltage generation circuit 30 supplies a second reference voltage to the address pin CA. In one exemplary embodiment, the second reference voltage generation circuit 30 includes a third resistor R3, a fourth resistor R4, a third capacitor C3, and a fourth capacitor C4. The third resistor R3 and the fourth resistor R4 are electronically connected in series between the power supply PVDDQ and ground. In one exemplary embodiment, the resistance value of the third resistor R3 and the fourth resistor R4 is about 100±0.5% ohms The address pin CA is electronically connected between the third resistor R3 and the fourth resistor R4, thus the second reference voltage generation circuit 30 supplies the second reference voltage of about 0.75V to the address pin CA. The third capacitor C3 is electronically connected to the fourth capacitor C4 in parallel. A first end the third capacitor C3 is electronically connected between the third resistor R3 and the fourth resistor R4, and a second end of the third capacitor C3 is connected to ground. A first end of the fourth capacitor C4 is electronically connected between the third resistor R3 and the fourth resistor R4, and a second end of the fourth capacitor C4 is connected to ground. Thus, any ripple of the second reference voltage is filtered by the third capacitor C3 and the fourth capacitor C4.

The second reference voltage generation circuit 30 is integrated on the memory 200, and is adjacent to the address pin CA. Thus, signal transmission length from the motherboard to the memory 200 is reduced, and the second reference voltage is less likely to be interfered with and distorted in the transmission process from the second reference voltage generation circuit 30 to the address pin CA.

Additionally, the first reference voltage and the second reference voltage can be sourced by the reference voltage generation circuit 100, and a microchip integrated on the motherboard to generate the first and second reference voltage is not needed.

Thus the memory 200 has, integrated within itself, the first reference voltage generation circuit 10 and the second reference voltage generation circuit 30 to supply the first reference voltage for the data pin DQ and the second reference voltage for the address pin CA respectively. The transmission distances of the first reference voltage and the second reference voltage are decreased to stabilize the first reference voltage and the second reference voltage. Therefore, the memory 200 with these features is both efficient and low in cost.

Although numerous characteristics and advantages of the exemplary embodiments have been set forth in the foregoing description, together with details of the structures and functions of the exemplary embodiments, the disclosure is illustrative only, and changes may be made in detail, especially in the matters of arrangement of parts within the principles of disclosure to the full extent indicated by the broad general meaning of the terms in which the appended claims are expressed.

What is claimed is:

1. A reference voltage generation circuit integrated on a memory, the memory comprising a data pin and an address pin, the reference voltage generation circuit comprising:
a first reference voltage generation circuit electronically connected to the data pin and supplying a first reference voltage to the data pin; and
a second reference voltage generation circuit electronically connected to the address pin and supplying a second reference voltage to the address pin.

2. The reference voltage generation circuit as claimed in claim 1, wherein the first reference voltage generation circuit includes a first resistor and a second resistor, the first resistor and the second resistor are electronically connected in series between a power supply and ground, and the data pin is electronically connected to a node between the first resistor and the second resistor.

3. The reference voltage generation circuit as claimed in claim 2, wherein the reference voltage generation circuit further includes a first capacitor and a second capacitor electronically connected to the first capacitor in parallel, a first end of the first capacitor electronically connected to the node between the first resistor and the second resistor, and a second end of the first capacitor is connected to ground, a first end of the second capacitor is electronically connected to the node between the first resistor and the second resistor, and a second end of the second capacitor connected to ground.

4. The reference voltage generation circuit as claimed in claim 1, wherein the second reference voltage generation circuit includes a third resistor and a fourth resistor, the third resistor and the fourth resistor are electronically connected in series between a power supply and ground, and the address pin is electronically connected to a node between the third resistor and the fourth resistor.

5. The reference voltage generation circuit as claimed in claim 4, wherein the reference voltage generation circuit further includes a third capacitor and a fourth capacitor electronically connected to the third capacitor in parallel, a first end of the third capacitor is electronically connected to the node between the third resistor and the fourth resistor, and a second end of the third capacitor is connected to ground, a first end of the fourth capacitor is electronically connected to the node between the third resistor and the fourth resistor, and a second end of the fourth capacitor is connected to ground.

6. A memory, comprising:
a data pin;
an address pin; and
a reference voltage generation circuit comprising:
a first reference voltage generation circuit electronically connected to the data pin and supplying a first reference voltage to the data pin; and
a second reference voltage generation circuit electronically connected to the address pin and supplying a second reference voltage to the address pin.

7. The memory as claimed in claim 6, wherein the first reference voltage generation circuit includes a first resistor and a second resistor, the first resistor and the second resistor are electronically connected in series between a power supply and ground, and the data pin is electronically connected to a node between the first resistor and the second resistor.

8. The memory as claimed in claim 7, wherein the reference voltage generation circuit further includes a first capacitor and a second capacitor electronically connected to the first capacitor in parallel, a first end of the first capacitor is electronically connected to the node between the first resistor and the second resistor, and a second end of the first capacitor is connected to ground, a first end of the second capacitor is electronically connected to the node between the first resistor and the second resistor, and a second end of the second capacitor is connected to ground.

9. The memory as claimed in claim 6, wherein the second reference voltage generation circuit includes a third resistor and a fourth resistor, the third resistor and the fourth resistor are electronically connected in series between a power supply and ground, and the address pin is electronically connected to a node between the third resistor and the fourth resistor.

10. The memory as claimed in claim 9, wherein the reference voltage generation circuit further includes a third capacitor and a fourth capacitor electronically connected to the third capacitor in parallel, a first end of the third capacitor is electronically connected to the node between the third resistor and the fourth resistor, and a second end of the third capacitor is connected to ground, a first end of the fourth capacitor is electronically connected to the node between the third resistor and the fourth resistor, and a second end of the fourth capacitor is connected to ground.
